(19) United States
(12) Patent Application Publication
(10) Pub. No.: US 2009/0257466 A1
(43) Pub. Date: Oct. 15, 2009

(54) Optoelectronic Semiconductor Component and Method for the Production of an Optoelectronic Semiconductor Device

(76) Inventors: Franz Eberhard, Regensburg (DE); Berthold Hahn, Hemau (DE); Stephan Kaiser, Regensburg (DE); Bernd Mayer, Regensburg (DE)

Correspondence Address: SLATER & MATSIL, L.L.P., 17950 PRESTON RD, SUITE 1000, DALLAS, TX, 75252-5793, US

(21) Appl. No.: 12/420,456

(22) Filed: Apr. 8, 2009

(30) Foreign Application Priority Data
Apr. 15, 2008 (DE) 10 2008 018 928.6

(51) Int. Cl. H01S 5/028; H01L 21/00

(52) U.S. Cl. 372/45.01; 438/38; 257/E21.002

(57) ABSTRACT

In at least one embodiment, the optoelectronic semiconductor component includes an optically active area that is formed with a crystalline semiconductor material that contains at least one of the substances gallium or aluminum. Furthermore, the semiconductor component contains at least one facet on the optically active area. Furthermore, the semiconductor component contains at least one boundary layer, containing sulfur or selenium, with a thickness of up to five monolayers, wherein the boundary layer is located on the facet. Such a semiconductor component has a high destruction threshold relative to the optical powers that occur during operation of the semiconductor component.

This patent application claims the priority of the German patent application 10 2008 018 928.6, filed Apr. 15, 2008, whose disclosed content is hereby incorporated by reference.

### TECHNICAL FIELD

An optoelectronic semiconductor component is disclosed. In addition, a method for the production of such an optoelectronic semiconductor component is specified.

### BACKGROUND

Optoelectronic semiconductor components, such as semiconductor lasers, can be found in many technical application fields. Optoelectronic semiconductor devices are useful due to properties such as compact construction, small space requirements, versatile embodiment possibilities, good efficiency and high degree of efficacy, as well as a good ability to set the relevant spectral region. For many application fields, optoelectronic semiconductor devices are desired that are highly luminous, have high intensities, and high optical output powers.

In European patent document EP 1 514 335 B1, equivalent U.S. Pat. No. 7,338,821, a method is described for the passivation of the reflective surfaces of optical semiconductor components.

U.S. Pat. No. 5,799,028 discloses a passivation and protection of a semiconductor surface.

### SUMMARY

One aspect of the invention specifies an optoelectronic semiconductor component that is suited for high optical output power. A further aspect specifies an efficient and simple method for producing such an optoelectronic semiconductor component.

According to at least one embodiment, the optoelectronic semiconductor component comprises at least one optically active area. The optically active area includes, at least in part, a crystalline semiconductor material. The semiconductor material forming the optically active area comprises at least one of the substances gallium or aluminum. For example, the optically active area has a p-n transition region. The optically active area can contain quantum well structures, quantum dot structures, or quantum line-like structures, either individually or in combination, or also p-n transition regions of planar construction. Possible components in which the optically active area can be used are, for instance, laser diodes, in particular, for near-infrared light, superluminescent diodes, or light-emitting diodes, in particular, high-power diodes, that is, diodes with an optical power of at least 0.5W, preferably those with an optical power of at least 1 W.

According to at least one embodiment, the optoelectronic semiconductor component has at least one facet on the optically active area. In particular, the semiconductor component can possess two facets located on opposite sides. Here, a facet is understood to be a smooth boundary surface. “Smooth” in this context means that the surface roughness of the facet is significantly smaller than the wavelength of the light to be generated by the optoelectronic semiconductor component in its operation, preferably less than half of the wavelength, particularly preferably, less than a quarter of the wavelength. Thus, the facet forms a boundary surface or an outer surface of the optically active area, such as between this and the surrounding air or another material with lower optical refractive index than that of the optically active area. The facet can be a polished surface. A facet can also be created on the optically active area by, for example, scoring and subsequently breaking the semiconductor material.

According to at least one embodiment, the optoelectronic semiconductor component comprises at least one boundary layer, containing sulfur or selenium. This is located on the facet. Preferably, the boundary layer is in direct contact with the facet. The boundary layer covers at least one part of the boundary surface formed by the facet, preferably the entire boundary surface. The thickness of the boundary layer amounts at most to ten monolayers, preferably to at most five monolayers. It is particularly preferable for the thickness of the boundary layer to amount to at most one monolayer. Here, a monolayer is understood as a crystal layer of the thickness of a unit cell of the semiconductor material. Preferably, no oxygen atoms are present in the boundary layer. That is, the boundary layer is free of oxygen atoms, where “free” means that the residual oxygen proportion amounts to less than 10 parts per billion (ppb), particularly preferably to less than 1 ppb.

In at least one embodiment, the optoelectronic semiconductor component comprises at least one optically active area that is formed with a crystalline semiconductor material containing at least one of the substances gallium or aluminum. Furthermore, the semiconductor component contains at least one facet on the optically active area. Furthermore, the semiconductor component contains at least one boundary layer containing sulfur or selenium, with a thickness of up to five monolayers, wherein the boundary layer is located on the facet. Such a semiconductor component has a high destruction threshold relative to the optical powers that occur during operation of the semiconductor component.

If semiconductor materials that contain at least one of the substances aluminum or gallium are exposed, for example, to air, in particular oxygen, an oxidation takes place. Consequently, an oxide layer forms at the semiconductor material/air boundary surface. This oxide layer and any additional impurities can form color centers, or absorption centers, that increasingly absorb, or reabsorb, light during operation of the optoelectronic semiconductor component. This leads to a local heating in the region of the impurities or oxidized areas. Depending on the semiconductor material used, this local heating can in turn lead to a lowering of the band gap of the semiconductor material, which intensifies the reabsorption. This causes the temperature in the area of the impurities to increase further.

The local heat build-up due to absorption or reabsorption can lead to fusion of the affected semiconductor regions, and thereby destroy the boundary surface, in particular, the facet. The efficiency of the affected optoelectronic semiconductor component is negatively impacted by this. If, for example, a reflective layer is deposited on the facet, the reflective layer can also be damaged. Specifically, the reflective layer can become detached from the facet due to local fusion. In particular, in the case of a laser resonator, in which the facet and a reflective layer applied upon it form at least one resonator mirror, this can lead to a destruction of the component, constructed, for example, in the form of a laser diode. This is also referred to as catastrophic optical damage (COD). The intensity threshold, or optical power threshold, at which the degradation mechanism starts is a quality criterion, for example, for a laser, and is referred to as a power catastrophic optical damage threshold (PCOD threshold).

This destruction mechanism can be eliminated, or shifted to significantly higher optical outputs, by preventing the facet from completely or partially oxidizing. The oxidation can be eliminated by applying a boundary layer to the facet, which at potential oxygen binding sites has atoms with a higher affinity to the semiconductor material of the optically active area than oxygen itself. This is attained by means of a boundary layer containing sulfur or selenium. Additionally, the boundary layer containing sulfur or selenium is transparent for the relevant radiation, for example, near-infrared laser radiation, so that no absorption or reabsorption occurs at the boundary layer.

According to at least one embodiment, the optoelectronic semiconductor component comprises at least one passivation layer on top of the boundary layer. The passivation layer covers at least parts of the boundary layer, and thus, also of the facet. Preferably, the passivation layer covers the entire boundary layer and also the entire boundary surface formed by the facet. Multiple passivation layers with different characteristics, arranged on top of each other, can serve, for instance, as adapter layers between the facet and additional layers to be deposited, for example, in order to enable adaptation of different crystal lattices to each other. Such a semiconductor element can be constructed in versatile ways and is robust against environmental influences, for example, oxidation and moisture.

According to at least one embodiment of the optoelectronic semiconductor component, the semiconductor material of the optically active area is based on gallium arsenide, aluminum gallium arsenide, indium gallium arsenide phosphide, gallium indium nitride arsenide, gallium nitride, indium gallium aluminum arsenide or gallium phosphide. Here, “based on” means that the essential component of the semiconductor material corresponds to one of the named compounds. The semiconductor material can also comprise other substances, in particular, dopants. By the use of such semiconductor materials, the frequency range to be emitted or to be received by the optically active area can be adjusted.

According to at least one embodiment of the optoelectronic semiconductor component, the boundary layer has gallium selenide, gallium sulphide, aluminum selenide, or aluminum sulphide. Selenium and sulfur have a high chemical affinity to gallium, and aluminum. In particular, the affinity of selenium and sulfur to gallium and aluminum can be higher than the affinity of oxygen to gallium and aluminum. This means that such a boundary layer prevents a damaging influence on the facet through oxidation.

According to at least one embodiment of the optoelectronic semiconductor component, the passivation layer is constructed with zinc selenide or zinc sulphide. Such a passivation layer can be produced simply, for example using metal organic vapor phase epitaxy (MOVPE), and offers good protection, for example against oxidation or moisture.

According to at least one embodiment of the optoelectronic semiconductor component, the thickness of the passivation layer amounts to at least 5 nm and at most 200 nm, preferably at least 10 nm and at most 100 nm, particularly preferably, at least 20 nm and at most 60 nm. A passivation layer constructed with such a thickness can be produced at reasonable manufacturing cost and offers sufficient protection of the semiconductor element, in particular of the optically active area, specifically against oxidation.

According to at least one embodiment, the optoelectronic semiconductor component comprises at least one dielectric layer sequence that is deposited in the form of a Bragg reflector on the passivation layer. A Bragg reflector is built from a number of dielectric layers with alternating high and low optical refraction indices. The number of layers is preferably between ten and twenty. The individual dielectric layers can be based on, for example, aluminum oxide, silicon oxide, tantalum oxide, silicon aluminum gallium arsenide, or aluminum gallium indium phosphide, depending on the spectral range for which the Bragg reflector is to be reflective. The Bragg reflector covers at least one part of the passivation layer, preferably the entire passivation layer, and therefore also the entire facet. Using a Bragg reflector, a resonator of high quality, for example, for a laser component, can be created in a simple way.

According to at least one embodiment, the optoelectronic semiconductor component is constructed as a laser bar. This means that the optoelectronic semiconductor component has, for example, an electrically or optically pumpable optically active area. Furthermore, the semiconductor component comprises a laser resonator that, for example, is formed by facets or boundary surfaces at the optically active area. Preferably, the laser bar also has electrical connection devices, in order to allow it to operate in the case that it is electrically pumped. A laser bar constructed this way has a high destruction threshold and is suitable for generating high optical output powers.

In addition, a method for the production of an optoelectronic semiconductor component is disclosed. For example, by means of the method an optoelectronic semiconductor component as described in connection with one or more of the embodiments named above, can be produced.

The method for producing an optoelectronic semiconductor component comprises, according to at least one embodiment, at least the following process steps. An optically active area whose semiconductor material contains at least one of the substances gallium or aluminum is provided. At least one facet is created on the optically active area. The facet is deoxidized by means of a gas stream containing sulfur or selenium. At least one boundary layer, containing selenium or sulfur, is created. This boundary layer is made of up to ten monolayers.

By means of a method designed in this way, an optoelectronic semiconductor component can be produced efficiently and comparatively simply.

Provision of the optically active area can include the fact that the active area is grown epitaxially on a growth substrate. In this case, the growth of the optically active area can occur in the wafer compound. The process step of providing the optically active area can also include separating the optically active area from a growth substrate or separating a growth substrate, for instance a wafer, into multiple components that can include one or more optically active areas.

The creation of at least one facet at the optically active area can occur by means of scoring and subsequent breaking, or also by means of cleaving. The boundary surface of the optically active area formed by the facet preferably has a roughness that is smaller than the wavelength of the electromagnetic radiation that is intended to be generated by the optoelectronic semiconductor component during its operation. Preferably the roughness is smaller than half of the wavelength, particularly preferably, less than a quarter of the wavelength. A facet that, for instance, has been sawn, can subsequently be smoothed by means of polishing or grinding. Preferably, two facets are created that are located essentially opposite each other, or arranged co-planar to each other, in particular, if the optoelectronic semiconductor component is intended to be used for laser applications, in such a way that the optically active area, together with the facets, is to form a resonator. Here, “essentially” means within the scope of the manufacturing tolerances.

Preferably, the deoxidization is performed using a gas stream containing sulfur or selenium. Here, the gas is guided over the facet, for example, similar to a MOVPE method. By this means, at the boundary surface of the semiconductor material forming the optically active area, the oxygen atoms located at and near the boundary surface are replaced by reactive selenium or sulfur atoms from the gas stream, whereby the deoxidization of the facet is realized.

A boundary layer created containing selenium or sulfur has a thickness of at most five monolayers, that is, the thickness of the boundary layer amounts at most to five unit cells of the crystal lattice of the semiconductor material. Preferably, only a single monolayer is formed. The thickness of the boundary layer corresponds preferably to at least the thickness of the oxygen-containing layer that is to be deoxidized. The monolayer preferably comprises at least one of the compounds gallium selenide, gallium sulphide, aluminum selenide, or aluminum sulphide.

According to at least one embodiment of the method, a passivation layer is formed on the boundary layer by means of a gas stream, for instance, similar to a MOVPE method. Preferably the passivation layer covers the entire boundary layer, which in turn preferably covers the entire boundary surface forming the facet. The passivation layer is formed, for instance, by a II-VI semiconductor material, preferably by zinc selenide or zinc sulphide. The material forming the passivation layer is preferably selected such that it can easily be grown on the boundary layer. If the boundary layer contains, for example, Ga(Al)₂Se₃, then ZnSe represents a particularly suitable material for the passivation layer. Such a method enables a simple production of a passivation film.

According to at least one embodiment of the method, the process steps deoxidization and creation of the boundary layer occur at atmospheric pressures greater than 10⁻³ mbar. This means that no high vacuum or ultrahigh vacuum is necessary for these process steps. During the deoxidization by means of a gas stream, and if applicable, during the creation of a passivation layer by means of a gas stream, atmospheric pressures in the range of 100 mbar to 1100 mbar preferably prevail, particularly preferably, between 300 mbar and 700 mbar. Because no high vacuum or ultrahigh vacuum is required, the production costs of the optoelectronic semiconductor component are reduced.

According to at least one embodiment of the method, deoxidization and deposition of the passivation layer occur in the same process chamber. This can be realized by bringing the optically active area to be treated into a chamber in which different gases can be streamed. For example, a first gas stream, of gas containing sulfur or selenium, is passed over the facet. Then, the flow is switched from the first gas stream to a second gas stream, which is used to grow the passivation layer. The switching is preferably performed quickly so that no gas containing oxygen reaches the facet. Here, “quickly” means, in particular, in less than one second. Therefore, the component to be treated need not be taken out of the process chamber between deoxidization and deposition of the passivation layer. This effectively prevents, any possible oxidation from taking place between deoxidization and the deposition of the passivation layer. Additionally, this simplifies the method because no process step of relocating the components to be treated is necessary.

According to at least one embodiment of the method for producing an optoelectronic semiconductor component, during the deoxidization, or during the deposition of the passivation layer respectively, a gas stream is used that contains at least one of the substances H₂, H₂Se, H₂S, a selenium metal organyl, a sulfur metal organyl, trimethyl zinc, diethyl zinc or a zinc organyl. The gas stream can, in particular, be a mixture of the above named substances. Also, additives can be added to the gas stream, for example, in order to achieve a doping. Through the use of substances listed above in the gas stream, an effective deoxidization and/or formation of the passivation layer is facilitated.

According to at least one embodiment of the method, the process temperature amounts in each case to at most 360° C., in particular during the steps deoxidization, creation of the boundary layer, and creation of the passivation layer. Preferably, the process temperature lies below 350° C., particularly preferably in the range between 260 and 300° C. Such process temperatures can guarantee that the optically active area is not damaged during the manufacturing process due to the process temperatures.

In particular, with such process temperatures, the reactive gas is not present as a high-energy or low-energy plasma. Because no plasma is present, the treatment of the semiconductor material forming the optically active area, and its facet, can occur particularly carefully.

According to at least one embodiment of the method the duration of the process steps deoxidization, creation of the boundary layer and/or deposition of the passivation layer is, in each case, less than six minutes, preferably less than three minutes, particularly preferably less than one minute. Due to the short time duration of the corresponding process steps, cost effective production of the optoelectronic semiconductor component is guaranteed.

According to at least one embodiment of the method, the components to be treated are grouped together during the process steps of deoxidization and/or deposition of the passivation layer. Here, “grouped together” means that a plurality of components to be treated is placed, for instance, in a regular pattern on a carrier. As a carrier, for instance, a plate, lattice, or wafer can be used. The carrier together with the components to be treated that are located on it are then introduced, for example, into a process chamber. The facets to be treated are preferably arranged in a plane, the boundary surfaces of the optically active areas formed by the facets are preferably aligned in the same direction. The components to be treated can be grouped together in such a way that their boundary surfaces not formed by the facets contact and cover one another at least in part, and thus are not deoxidized or passivated. Preferably, the components to be treated are formed in a cuboid shape and the facets to be treated are formed by face surfaces of the cuboid. By grouping together the components to be treated, an efficient and cost effective method is possible.

The specified sequence of process steps is to be regarded as preferred. However, deviating sequences are also possible, depending on the requirements.

### BRIEF DESCRIPTION OF THE DRAWINGS

In the following, the optoelectronic semiconductor component described here, as well as the method for producing a semiconductor component, are explained in more detail using exemplary embodiments and the associated figures, which shows:

FIG. 1 shows a schematic side view of an exemplary embodiment of an optoelectronic semiconductor component;

FIG. 2 shows a schematic side view of a further exemplary embodiment of a semiconductor component;

FIG. 3 shows a schematic side view of an exemplary embodiment of a semiconductor component (a) in the form of a laser bar and a schematic side view (b) of a laser stack;

FIG. 4 shows a schematic side view of a further exemplary embodiment of a semiconductor element in the form of a vertical emitting laser;

FIG. 5 shows a schematic three dimensional representation of grouped components; and

FIGS. 6a to 6f show a schematic illustration of different process steps for producing an optoelectronic semiconductor component.

In the exemplary embodiments and figures, equivalent components or components that have the same effect, are designated respectively with the same reference numbers. The elements illustrated are not to be regarded as true to scale; rather, individual elements can be represented in exaggerated size for better comprehension.

### DETAILED DESCRIPTION

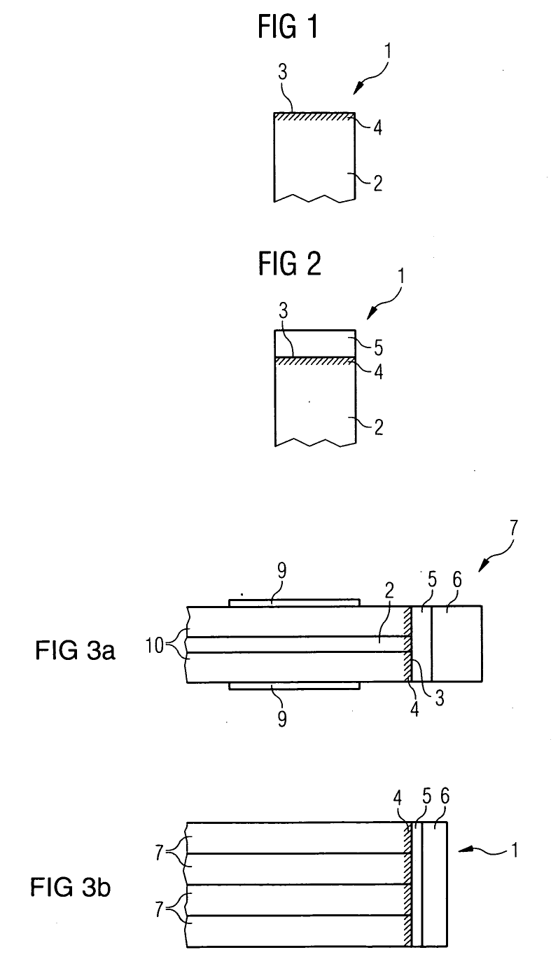

FIG. 1 shows an exemplary embodiment of an optoelectronic semiconductor component 1. On the optically active area 2, which is based, for instance, on AlGaAs, a facet 3 is created. The facet 3 represents a smooth boundary surface on the optically active area 2 to the environment. A boundary layer 4 is applied over the entire surface area of the facet 3. The boundary layer 4 is formed from a monolayer of Ga(Al)₂Se₃. This monolayer has the thickness of one unit cell of the crystal lattice. Due to the high affinity of selenium to gallium and aluminum, oxidation of the facet 3 is prevented.

In the exemplary embodiment according to FIG. 2, a passivation layer 5 is additionally deposited on the boundary layer 4. The semiconductor material of the optically active area 2 is based, for example, on InGaAlP. The boundary layer 4 contains sulfur. The passivation layer 5 has a thickness of approximately 50 nm and is composed of ZnS. The Ga(Al)₂S₃ present in the boundary layer 4 provides a good growth base for ZnS. Due to the low thickness of the passivation layer 5, lattice mismatches between the boundary layer 4 and the passivation layer 5 possibly lead to dislocations in the crystal lattice, however, not to grain boundaries, so that the passivation layer 5 is sealed, for example, against oxygen. Thus, the passivation layer 5 fulfills the function of protecting the boundary layer 4, which is unstable in an oxygen-containing atmosphere, in particular, air, from the effects of air or oxidation.

Alternatively, the boundary layer 4 can also be formed by Ga(Al)₂Se₃, then, the passivation layer 5 preferably comprises ZnSe. Along with ZnS and ZnSe, suitable passivation layers 5 are formed, for example, from II-VI semiconductors such as CdSe, CdS, CdTe, ZnTe and BeTe, or also from MgTe or MgSe.

The passivation layer 5 is composed preferably of a material that is transparent to the wavelengths occurring during operation of the optoelectronic semiconductor component 1. ZnSe is transparent at wavelengths longer than approximately 550 nm, ZnS at wavelengths longer than approximately 370 nm, depending on the crystal structure. Likewise, the materials of the boundary layer 4 and the passivation layer 5 must be suitably matched to each other, for example regarding the lattice constants of the crystal lattices.

An alternative or additional possibility to protect a facet 3 from destruction due to absorption or reabsorption, consists of destroying the radiation-generating or radiation-absorbing structures in an optically active area 2 in the proximity of the facet 3. This is possible by the dissolving, for example, of quantum wells in the optically active area 2, so called quantum well intermixing (QWI). Here, for example, impurities are brought, for instance through diffusion, into the crystal structures of the regions located close to the facet 3 of the optically active area 2, which causes this to be deactivated.

An exemplary embodiment in the form of a laser bar 7 is illustrated in FIG. 3a. An optically active area 2 is enclosed by semiconductor layers 10, to which in turn electrodes 9 are applied for the current supply. The optically active area 2 is based, for example, on AlGaN. A boundary layer 4 is located on the facet 3, which can be created by breaking. The thickness of the boundary layer 4 amounts to one monolayer. The boundary layer 4 in this exemplary embodiment is aligned essentially parallel to the growth direction of the semiconductor layers 10, or of the optically active area 2. A passivation layer 5 with a thickness of approximately 20 nm is deposited on the boundary layer 4. The boundary layer 4 and passivation layer 5 both cover the entire boundary surface formed by the facet 3. On the side of passivation layer 5 facing away from the facet 3, a dielectric layer sequence 6 is deposited that is constructed as a Bragg reflector. The Bragg reflector is composed of a layer sequence with alternating high and low refractive indices. The electric layer can be based on, for example, zinc selenide, aluminum oxide, silicon dioxide, tatalum oxide, or silicon. The passivation layer 5 can also constitute a part of the Bragg reflector. Together with a second Bragg reflector, not shown, on the boundary surface, also not shown, located opposite the facet 3, the first Bragg reflector forms a resonator, for example, for a semiconductor laser emitting in the near infrared.

The optoelectronic semiconductor component 1 in the form of a laser stack can then be formed, as shown in FIG. 3b, from a plurality of piled or stacked laser bars 7. Depending on the specific construction of the laser bars 7, it can be advantageous that a continuous boundary layer 4 or passivation layer 5 is formed over all the facets 3 of the various laser bars 7.

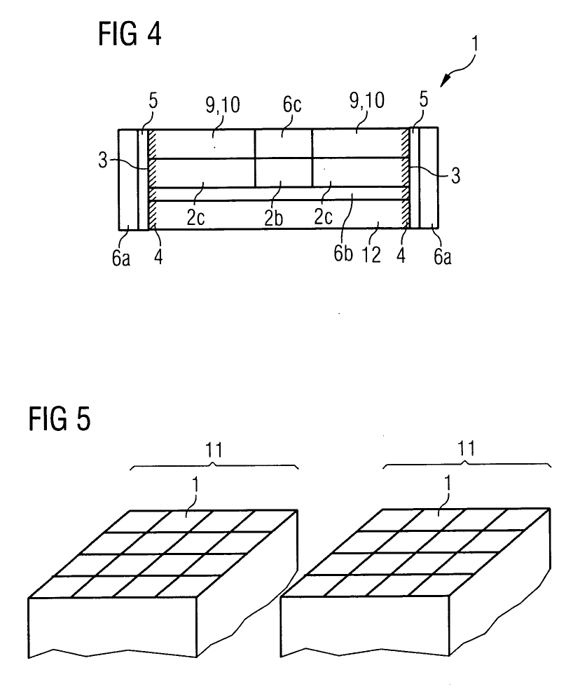

According to FIG. 4, the optoelectronic semiconductor component 1 is formed by a vertically emitting, for example, optically pumped, semiconductor laser (VECSEL). A first dielectric layer sequence 6b, which forms a first Bragg reflector 6b, is deposited onto a substrate 12 formed, for instance, with a semiconductor material. Optically active areas 2b and 2c are arranged on the side of a first Bragg reflector 6b facing away from the substrate 12. Electrodes 9 and semiconductor layers 10 are applied to the side of the optically active areas 2c facing away from the substrate 12. Via these electrodes and layers, the areas 2c can be electrically pumped, and thereby form a first laser, the resonator of which is formed by two second Bragg reflectors 6a. The second Bragg reflectors 6a are applied over the facets 3 as the farthest outlying components. The facets 3 constitute the lateral outer boundary surfaces of the optically active areas 2c, of the substrate 12, and of the semiconductor layers 10. Boundary layers 4 are applied to the facets 3 of the first electrically pumped laser. The boundary layers 4 are, in turn, covered by passivation layers 5, wherein boundary layers 4 and passivation layers 5 cover the entire boundary surfaces formed by the facets 3. Thus, boundary layers 4 and passivation layers 5 protect not only the optically active areas 2c, but also the semiconductor material surrounding these.

The vertically emitting optically active area 2b, pumped by the first laser, is covered by a third Bragg reflector 6c that together with the first Bragg reflector 6b forms the resonator of the VECSEL.

As well as horizontally emitting lasers, as shown in FIG. 3, or vertically emitting lasers, as represented in FIG. 4, boundary layers containing sulfur or selenium can also be used in light emitting diodes and superluminescent diodes. Other components also, in which high light intensities occur at the boundary surfaces and which have at least one semiconductor material that contains at least one of the substances gallium or aluminum, can be equipped with the described type of oxidation protection and/or a passivation.

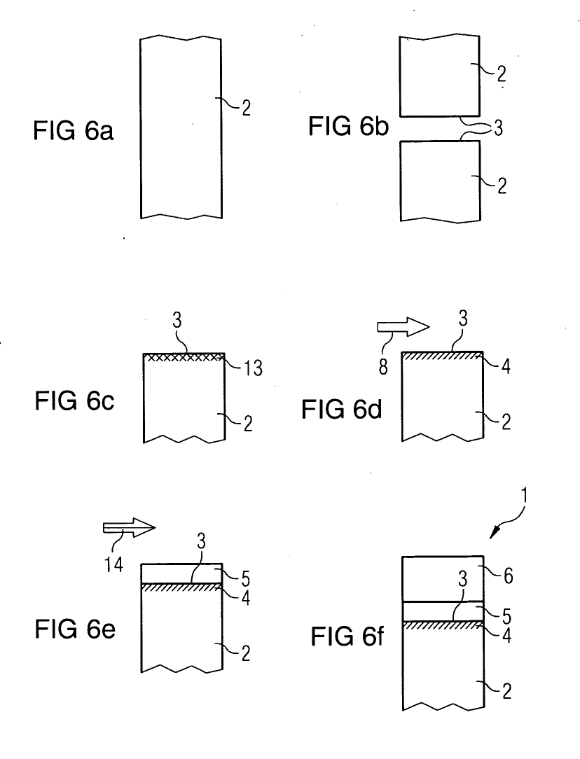

A method for producing an optoelectronic component 1 is schematically represented in FIG. 6, which includes FIGS. 6a-6f.

In FIG. 6a, an optically active area 2 is provided. The optically active area 2 can be a layer with quantum points, quantum wells, or quantum lines, or can also contain one or more planar p-n transition regions. The optically active area 2 can also be formed by heterostructures. In particular, provision of the optically active area 2 can occur by epitaxial growth on a substrate, such as a wafer.

In FIG. 6b the production of the facet 3 is represented schematically. Optically active areas 2 present, for example, as wafers are scored and subsequently broken such that smooth boundary surfaces arise that form facets 3. In order to keep the cost of creating of the facets 3 low, and to enable simple handling, the facets 3 are preferably created in air.

Because the semiconductor material forming the optically active area 2 is based on, for example, gallium arsenide, gallium phosphide, or gallium nitride, an oxidation layer 13 forms on the facets 3 in air (FIG. 6c). This oxidation layer 13 and possible additional impurities form locally absorbing structures that can lead to later damage of the optoelectronic semiconductor component 1. Therefore, the oxidation layer 13, which can contain gallium oxide and/or aluminum oxide, must be removed in order to guarantee a long service life for the semiconductor element 1.

This occurs as shown in FIG. 6d, preferably with a gas stream 8 containing highly reactive selenium or sulfur. Preferably, the gas flow 8 is formed by H₂Se. This causes the oxygen in the oxide layer 13 to be essentially substituted by selenium, and a boundary layer 4 containing selenium forms on the facet 3. The process temperature during this process step lies preferably between 260° C. and 300° C. At these temperatures, no damage occurs, for example, to the optically active area 2 designed for use in a laser diode. The atmospheric pressure during the deoxidization amounts to a few hundred mbar. Thus, no complex and therefore, cost-intensive high vacuum or ultrahigh vacuum environment is necessary. At the process conditions described, the duration of the oxidation amounts to less than one minute.

After the deoxidization by means of the gas stream 8, without pause, a switch occurs to another gas flow 14, via which the passivation layer 5 is deposited. If the passivation layer 5 is composed of zinc selenide, then the gas flow 14 is composed, for instance, of a mixture of gases containing selenium and zinc, for example, of H₂Se and trimethyl zinc. Again, this process takes place at pressures of a few hundred mbar. This process step preferably takes place in the same process chamber as the deoxidization, so that no relocation of the components to be passivated is necessary.

The exact stoichiometry and the thickness of the passivation layer 5 depend on the respective requirements. Preferably, the thickness amounts to roughly 50 nm. The growth rate of the zinc selenium layer is approximately a few hundred nanometers per minute, such that the process step of the growth of the passivation layer 5 can also proceed within a timescale of seconds, and therefore requires only a short amount of time.

The process steps of deoxidization, according to FIG. 6d, and the growth of the passivation layer 5, according to FIG. 6e, proceed preferably with the optically active areas 2 grouped together in a group 11, as shown in FIG. 5. The optoelectronic semiconductor components 1 that have, for example, cuboid-shaped geometries and are grouped together are layered on top of each other so that the facets 3 to be deoxidized and coated are arranged, for instance, in a plane and aligned parallel to each other. The side surfaces of the component 1 not formed by the facets 3 are preferably arranged such that they contact each other, at least in part, and thus no coating or contamination of the side surfaces not formed by the facets 3, takes place. Depending on the requirements, several groups 11 formed in this way can be placed on a carrier, not shown.

The facets 3 have surface areas, for example, on the order of one square millimeter. Thus, with an assumed carrier diameter of roughly 100 mm, roughly 1,000 individual semiconductor components 1 can be handled easily in one batch. After deoxidization and passivation of the facets 3, the group 11 can be removed from the process chamber, and can, for example, be turned such that facets located opposite the facets 3 shown can also be processed, if necessary. Because the stated process steps do not require vacuum conditions, the handling is significantly simplified. With the named surfaces to be processed, gas flow rates of the reaction gas streams 8, 14 of only about 30 μmol/min are necessary. Thereby, the material expenditure is comparatively low. The method can be scaled easily for larger lots.

In a further, optional process step according to FIG. 6f, a dielectric layer sequence 6 can be deposited, for instance, by means of MOVPE.

Using this method, components such as those shown in the FIGS. 1 to 4 can be produced.

An alternative method of protecting a facet 3 from oxidation consists in creating the facet 3, for instance by breaking, in an ultrahigh vacuum (UHV), and likewise to passivate under UHV conditions. Certainly, creating facets 3 in the UHV is costly. Additionally, at pressures of typically less than 10⁻⁸ mbar, oxidation of the facet 3 is not completely prevented, but rather only significantly reduced. In principle, the danger of a COD still exists.

Another alternative possibility is for the facets 3 to be created in air, and subsequently further processed in UHV. The facets 3 can be cleaned, for example, by means of a H₂ plasma under UHV conditions. With this method also, oxide residues remain on the facets 3. Furthermore, UHV technology is cost-intensive and can be scaled only in limited ways for larger surfaces to be processed and larger lots.

The invention described here is not limited by the description using the exemplary embodiments. Rather, the invention comprises each new feature and each combination of features, which includes, in particular, each combination of features in the patent claims. This applies also if this feature or this combination is not itself explicitly disclosed in the patent claims or exemplary embodiments.

1. An optoelectronic semiconductor component comprising:
an optically active area with a crystalline semiconductor material containing at least one of gallium and/or aluminum;
a facet on the optically active area; and
a boundary layer on the facet, the boundary layer containing sulfur or selenium and composed of up to ten monolayers.

2. The optoelectronic semiconductor component according to claim 1, further comprising a passivation layer on the boundary layer.

3. The optoelectronic semiconductor component according to claim 1, wherein the boundary layer comprises GaSe, GaS, AlSe or AlS.

4. The optoelectronic semiconductor component according to claim 2, wherein the passivation layer comprises ZnSe or ZnS.

5. The optoelectronic semiconductor component according to claim 2, wherein the passivation layer has a thickness between about 5 nm and 200 nm.

6. The optoelectronic semiconductor component according to claim 2, further comprising a dielectric layer sequence in the form of a Bragg reflector on the passivation layer.

7. The optoelectronic semiconductor component according to claim 1, wherein the semiconductor component comprises a laser bar.

8. A method for producing an optoelectronic semiconductor component, the method comprising:
providing an optically active area comprising a semiconductor material that contains gallium and/or aluminum;
forming a facet on the optically active area;
deoxidizing the facet by means of a gas stream containing sulfur or selenium; and
forming a boundary layer containing sulfur or selenium, the boundary layer having up to ten monolayers.

9. The method according to claim 8, further comprising depositing a passivation layer by means of a second gas stream.

10. The method according to claim 8, wherein the deoxidizing and forming the boundary layer are performed at an atmospheric pressure that is greater than 10⁻³ mbar.

11. The method according to claim 9, wherein the deoxidizing and depositing the passivation layer take place in a same process chamber.

12. The method according to claim 9, wherein the gas stream for deoxidizing or the second gas stream for depositing the passivation layer contains at least one of the following substances: H₂, H₂Se, H₂S, a Se metal organyl, a S metal organyl, Trimethyl Zn, diethyl Zn, a Zn organyl.

13. The method according to claim 8, wherein the optoelectronic semiconductor component is formed at a process temperature below a maximum of 360° C.

14. The method according to claim 9, wherein deoxidizing and/or depositing the passivation layer is performed for a duration of less than 6 minutes.

15. The method according to claim 9, wherein, at least during the deoxidizing and/or depositing of the passivation layer, the semiconductor component is one semiconductor component in a group of semiconductor components that are being processed simultaneously.
